(19) United States
(12) Patent Application Publication
(10) Pub. No.: US 2026/0089846 A1
(43) Pub. Date: Mar. 26, 2026

(54) METHOD AND SYSTEM OF MANUFACTURING PRINTED WIRING BOARD

(71) Applicant: SUMITOMO ELECTRIC PRINTED CIRCUITS, INC., Shiga (JP)

(72) Inventors: Takeshi HAMADA, Shiga (JP); Yuichi IDOMOTO, Shiga (JP); Takashi KASUGA, Shiga (JP); Wooseung DO, Shiga (JP); Takahiko MAKINO, Shiga (JP)

(73) Assignee: SUMITOMO ELECTRIC PRINTED CIRCUITS, INC., Shiga (JP)

(21) Appl. No.: 19/110,510

(22) PCT Filed: Apr. 28, 2023
(86) PCT No.: PCT/JP2023/016934

§ 371 Date: Mar. 11, 2025

(30) Foreign Application Priority Data
Sep. 15, 2022 (JP) 2022-147170

(51) Int. Cl. H05K 3/22

(52) U.S. Cl. CPC H05K 3/22; H05K 2203/108; H05K 2203/176

(57) ABSTRACT

A method of manufacturing a printed wiring board according to one aspect of the present disclosure is a method of manufacturing a printed wiring board from a printed wiring board sheet having a plurality of printed wiring board pieces. The method includes: determining, by an electrical inspection, whether each of the plurality of printed wiring board pieces is a non-defective product or a defective product; after the determining, selectively cutting out the non-defective product from the printed wiring board sheet; and inspecting an appearance of the non-defective product cut out in the cutting out. The method further includes passing on data about a non-defective product or a defective product to the cutting out, the data about a non-defective product or a defective product being obtained in the determining. In the cutting out, the non-defective product is cut out based on the data passed on in the passing on.

### TECHNICAL FIELD

The present disclosure relates to a method and system of manufacturing a printed wiring board.

The present application claims priority based on Japanese Patent Application No. 2022-147170 filed on Sep. 15, 2022, the entire contents of which are incorporated herein by reference.

### BACKGROUND ART

As a method of efficiently manufacturing a printed wiring board, there is known a method of preparing one large-sized printed wiring board sheet and cutting out a plurality of printed wiring board pieces from the printed wiring board sheet (see PTL 1).

### CITATION LIST

### Patent Literature

PTL 1: Japanese Patent Laying-Open No. 2006-319067

### SUMMARY OF INVENTION

A method of manufacturing a printed wiring board according to one aspect of the present disclosure is a method of manufacturing a printed wiring board from a printed wiring board sheet having a plurality of printed wiring board pieces. The method includes: determining, by an electrical inspection, whether each of the plurality of printed wiring board pieces is a non-defective product or a defective product; after the determining, selectively cutting out the non-defective product from the printed wiring board sheet; and inspecting an appearance of the non-defective product cut out in the cutting out. The method further includes passing on data about a non-defective product or a defective product to the cutting out, the data about a non-defective product or a defective product being obtained in the determining. In the cutting out, the non-defective product is cut out based on the data passed on in the passing on.

### BRIEF DESCRIPTION OF DRAWINGS

FIG. 1 is a flowchart illustrating a method of manufacturing a printed wiring board according to one embodiment of the present disclosure.

FIG. 2 is a schematic diagram showing a determining step in the method of manufacturing a printed wiring board in FIG. 1.

FIG. 3 is a schematic plan view showing a state in which a printed wiring board sheet is held by a first jig in the determining step in FIG. 2.

FIG. 4 is a schematic plan view corresponding to that in FIG. 3 and showing a state after a determination made in the determining step in FIG. 2.

FIG. 5 is a schematic diagram showing a cutting-out step in the method of manufacturing a printed wiring board in FIG. 1.

FIG. 6 is a partially enlarged schematic cross-sectional view showing a state in which a non-defective product has been cut out in the cutting-out step in FIG. 5.

FIG. 7 is a schematic diagram showing an appearance inspecting step in the method of manufacturing a printed wiring board in FIG. 1.

FIG. 8 is a flowchart illustrating a method of manufacturing a printed wiring board according to an embodiment different from that in the method of manufacturing a printed wiring board in FIG. 1.

### DETAILED DESCRIPTION

### Problem to be Solved by the Present Disclosure

PTL 1 discloses a method of manufacturing a printed wiring board from a workpiece having a plurality of singulated substrate portions. PTL 1 discloses that a continuity test is performed on the workpiece, from which the singulated substrate portions are then punched out.

According to the method of manufacturing a printed wiring board disclosed in PTL 1, the singulated substrate portions each determined as a non-defective product by the continuity test and the singulated substrate portions each determined as a defective product by the continuity test are both punched out. Thus, according to the configuration disclosed in PTL 1, defective products may be mixed into non-defective products due to such punching out of the defective products. Further, according to the configuration disclosed in PTL 1, the manufacturing efficiency may not be sufficiently enhanced.

The present disclosure has been made in view of the above-described circumstances, and an object thereof is to provide a method of manufacturing a printed wiring board, by which the efficiency in manufacturing of a printed wiring board can be enhanced while suppressing mixing of defective products into non-defective products.

### Advantageous Effect of the Present Disclosure

The method of manufacturing a printed wiring board according to one aspect of the present disclosure makes it possible to enhance the efficiency in manufacturing of the printed wiring board while suppressing mixing of defective products into non-defective products.

### Description of Embodiments of the Present Disclosure

First, embodiments of the present disclosure will be listed and described.

(1) A method of manufacturing a printed wiring board according to one aspect of the present disclosure is a method of manufacturing a printed wiring board from a printed wiring board sheet having a plurality of printed wiring board pieces. The method includes: determining, by an electrical inspection, whether each of the plurality of printed wiring board pieces is a non-defective product or a defective product; after the determining, selectively cutting out the non-defective product from the printed wiring board sheet; and inspecting an appearance of the non-defective product cut out in the cutting out. The method further includes passing on data about a non-defective product or a defective product to the cutting out, the data about a non-defective product or a defective product being obtained in the determining. In the cutting out, the non-defective product is cut out based on the data passed on in the passing on.

The method of manufacturing a printed wiring board includes passing on the data about a non-defective product or a defective product obtained in the determining to the cutting out, and in the cutting out, the non-defective product is selectively cut out from the printed wiring board sheet based on the data passed on in the passing on. According to the method of manufacturing a printed wiring board, the defective product is not cut out from the printed wiring board sheet, which makes it possible to suppress mixing of the defective products into the non-defective products. Further, according to the method of manufacturing a printed wiring board, only each non-defective product cut out in the cutting out can be inspected in the inspecting an appearance, so that the efficiency in manufacturing of the printed wiring board can be enhanced.

(2) In the above-described (1), in the determining, an identification mark may be attached to the defective product. In this way, the identification mark is attached to the defective product in the determining, which makes it possible to more reliably suppress mixing of the defective products into the non-defective products.

(3) In the above-described (2), in the determining, the identification mark may be attached by a first laser beam, and, in the cutting out, the non-defective product may be cut out by a second laser beam higher in intensity than the first laser beam. In this way, the identification mark is attached by the first laser beam in the determining, and the non-defective product is cut out by the second laser beam higher in intensity than the first laser beam in the cutting out, which makes it possible to easily and reliably attach the identification mark and cut out the non-defective product.

(4) In any one of the above-described (1) to (3), in the determining, the printed wiring board sheet may be held by a first jig, and the first jig may be provided with a non-contact tag capable of storing non-defectiveness/defectiveness determination data obtained in the determining. In this way, in the determining, the printed wiring board sheet is held by the first jig, and the first jig is provided with the non-contact tag capable of storing the non-defectiveness/defectiveness determination data obtained in the determining, which makes it possible to more reliably suppress mixing of the defective products into the non-defective products.

(5) In any one of the above-described (1) to (4), in the cutting out, the printed wiring board sheet may be held by a second jig, and the second jig may have a receiving portion that receives the non-defective product cut out from the printed wiring board sheet. In this way, in the cutting out, the printed wiring board sheet is held by the second jig, and the second jig has the receiving portion for receiving the non-defective product cut out from the printed wiring board sheet, which makes it possible to easily and reliably separate each non-defective product from the printed wiring board sheet still including the defective products.

(6) In any one of the above-described (1) to (5), the method may further include feeding back data about a defective product to a step prior to the determining in order to reduce defective products in number, the data about a defective product being obtained in the determining. In this way, the method further includes feeding back the data about a defective product obtained in the determining to a step prior to the determining in order to reduce the number of defective products, which makes it easy to suppress the occurrence of the defective product. As a result, the efficiency in manufacturing of the printed wiring board can be further enhanced.

(7) A system of manufacturing a printed wiring board according to another aspect of the present disclosure is a system of manufacturing a printed wiring board from a printed wiring board sheet having a plurality of printed wiring board pieces. The system includes: a determination device that determines, by an electrical inspection, whether each of the plurality of printed wiring board pieces is a non-defective product or a defective product; a cutting device that selectively cuts out the non-defective product from the printed wiring board sheet; and an appearance inspection device that inspects an appearance of the non-defective product cut out by the cutting device. The system further includes a data controller that passes on data about a non-defective product or a defective product to the cutting device, the data about a non-defective product or a defective product being obtained in the determination device. The cutting device cuts out the non-defective product based on the data passed on from the data controller.

According to the system of manufacturing a printed wiring board, the cutting device can selectively cut out the non-defective product from the printed wiring board sheet based on the data passed on from the data controller. In the system of manufacturing a printed wiring board, each defective product is not cut out from the printed wiring board sheet, which makes it possible to suppress mixing of the defective products into the non-defective products. Further, according to the system of manufacturing a printed wiring board, the appearance inspection device can inspect only the non-defective product that has been cut out by the cutting device, which makes it possible to enhance the efficiency in manufacturing of the printed wiring board.

### Details of Embodiments of the Present Disclosure

Hereinafter, preferred embodiments of the present disclosure will be described with reference to the accompanying drawings. Note that each of the figures is schematically shown, and the shapes, dimensions, ratios, and the like shown in each figure may not correspond to actual shapes, dimensions, ratios, and the like. Further, the expressions “first”, “second”, and the like in the present disclosure do not indicate the priority.

### First Embodiment

### Method of Manufacturing Printed Wiring Board

A method of manufacturing a printed wiring board according to one aspect of the present disclosure is a method of manufacturing a printed wiring board from a printed wiring board sheet having a plurality of printed wiring board pieces. In the method of manufacturing a printed wiring board, a plurality of printed wiring boards are manufactured from one large-sized printed wiring board sheet.

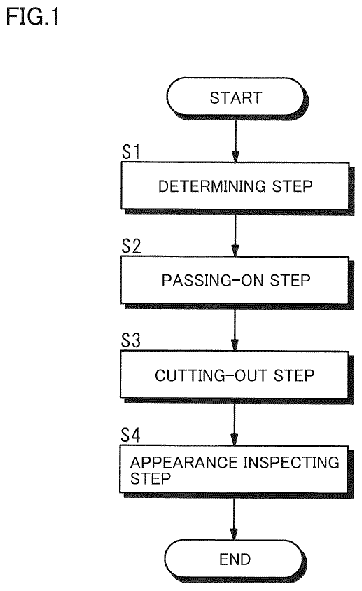

As shown in FIG. 1, the method of manufacturing a printed wiring board includes: a determining step S1 of determining, by an electrical inspection, whether each of the plurality of printed wiring board pieces is a non-defective product or a defective product; a cutting-out step S3 of, after the determining step S1, selectively cutting out the non-defective product from the printed wiring board sheet; and an appearance inspecting step S4 of inspecting an appearance of the non-defective product that has been cut out in the cutting-out step S3. Further, the method of manufacturing a printed wiring board includes a passing step S2 of passing on data about a non-defective product or a defective product obtained in the determining step S1 to the cutting-out step S3. According to the method of manufacturing a printed wiring board, in the cutting-out step S3, the non-defective product is cut out based on the data passed on in the passing step S2.

The method of manufacturing a printed wiring board includes the passing step S2 of passing on the data about a non-defective product or a defective product obtained in the determining step S1 to the cutting-out step S3, and, in the cutting-out step S3, the non-defective product is selectively cut out from the printed wiring board sheet based on the data passed on in the passing step S2. According to the method of manufacturing a printed wiring board, each of the defective products is not cut out from the printed wiring board sheet, which makes it possible to suppress mixing of the defective products into the non-defective products. Further, such a configuration makes it possible to reduce the loss resulting from processing of the defective products. Further, according to the method of manufacturing a printed wiring board, in the appearance inspecting step S4, only the non-defective product cut out in the cutting-out step S3 can be inspected, so that the efficiency in manufacturing of the printed wiring board can be enhanced.

According to the method of manufacturing a printed wiring board, each of the printed wiring board pieces determined as non-defective products in the appearance inspecting step S4 is manufactured as a printed wiring board after being subjected to other steps as required. On the printed wiring board sheet, for example, the plurality of printed wiring board pieces are regularly arranged. The lower limit of the number of the printed wiring board pieces arranged on the printed wiring board sheet may be, for example, 10, 30, or 50. The upper limit of the number of the printed wiring board pieces arranged on the printed wiring board sheet may be, for example, 500, 300, or 100.

The printed wiring board piece includes a substrate having an insulating property and a conductive pattern disposed on the substrate. The substrate may be a rigid substrate, a flexible substrate having flexibility, or a composite substrate having the rigid substrate and the flexible substrate integrated with each other. The conductive pattern has one or a plurality of wiring portions. The conductive pattern may be disposed on only one surface of the substrate or may be disposed on both surfaces of the substrate. The main component of the conductive pattern is not particularly limited but may be copper, for example.

Hereinafter, each of the steps in the method of manufacturing a printed wiring board will be described in detail.

### Determining Step

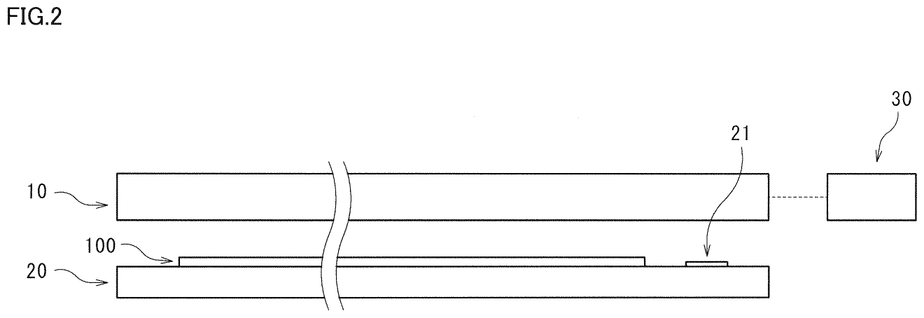

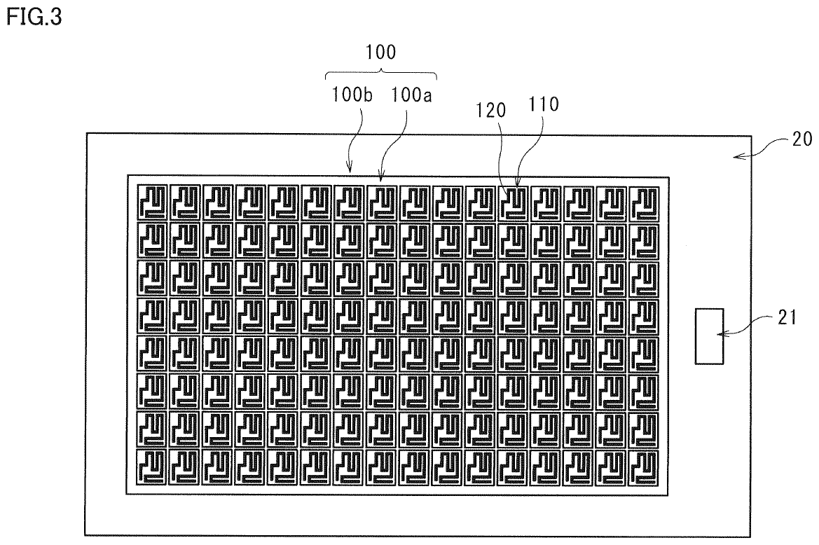

In the determining step S1, as shown in FIGS. 2 and 3, an electrical inspection device 10 is used to electrically inspect a plurality of printed wiring board pieces 110 included in a printed wiring board sheet 100. A specific configuration of electrical inspection device 10 is not particularly limited but, for example, may be a configuration including a plurality of probes. For example, with use of the plurality of probes, electrical inspection device 10 inspects whether a short circuit occurs or not in a conductive pattern 120.

As shown in FIG. 3, printed wiring board sheet 100 includes: an array portion 100a in which a plurality of printed wiring board pieces 110 are arranged in a matrix; and an annular peripheral portion 100b disposed around array portion 100a. Printed wiring board sheet 100 has a grid-like connection portion in array portion 100a. The connecting portion extends from the inner peripheral edge of peripheral portion 100b. The plurality of printed wiring board pieces 110 are connected to the connection portion. In other words, printed wiring board pieces 110 adjacent to each other in array portion 100a are connected by the connection portion. Each printed wiring board piece 110 located at the outermost periphery in array portion 100a is connected to peripheral portion 100b by the connection portion. The plurality of printed wiring board pieces 110 are arranged at intervals with the connection portion being interposed therebetween.

In the determining step S1, an electrical inspection is performed on conductive pattern 120 of each of the plurality of printed wiring board pieces 110 included in printed wiring board sheet 100. In the determining step S1, one electrical inspection or a plurality of electrical inspections may be performed on each printed wiring board piece 110. When a plurality of electrical inspections are performed on each printed wiring board piece 110 in the determining step S1, the wiring portion to be inspected in each electrical inspection may be the same or different. In the method of manufacturing a printed wiring board, the step of electrically inspecting conductive pattern 120 may not be performed after the determining step S1. In the method of manufacturing a printed wiring board, the electrical inspection of conductive pattern 120 is ended in the determining step S1, so that the printed wiring board can be manufactured more efficiently.

As shown in FIG. 3, in the determining step S1, an electrical inspection is performed in the state in which printed wiring board sheet 100 is held by a first jig 20. First jig 20 is, for example, a plate member capable of supporting printed wiring board sheet 100. First jig 20 may have a positioning portion for determining the position of printed wiring board sheet 100 with respect to first jig 20 and the position of first jig 20 with respect to electrical inspection device 10.

First jig 20 is provided with a non-contact tag 21 capable of storing non-defectiveness/defectiveness determination data obtained in the determining step S1. Examples of non-contact tag 21 include a radio frequency identification (RFID) tag. Since first jig 20 is provided with non-contact tag 21, it is possible to more reliably suppress mixing of the defective products into the non-defective products in the subsequent steps.

Non-contact tag 21 stores the non-defectiveness/defectiveness determination data in units of printed wiring board pieces 110. Non-contact tag 21 may store, as the non-defectiveness/defectiveness determination data, a specific location of printed wiring board piece 110 that has been determined as a defective product in one printed wiring board sheet 100. In other words, non-contact tag 21 may store the data about arrangement of the defective products in printed wiring board sheet 100 as the non-defectiveness/defectiveness determination data.

When a plurality of electrical inspections are performed on each printed wiring board piece 110 in the determining step S1, the electrical inspection result of each electrical inspection is stored in non-contact tag 21. Non-contact tag 21 may also be overwritten with an electrical inspection result for each electrical inspection. Using non-contact tag 21 in the determining step S1, for example, makes it possible to easily trace whether or not defective products may be mixed in printed wiring board pieces 110 that have been cut out in the cutting-out step S3, which will be described later.

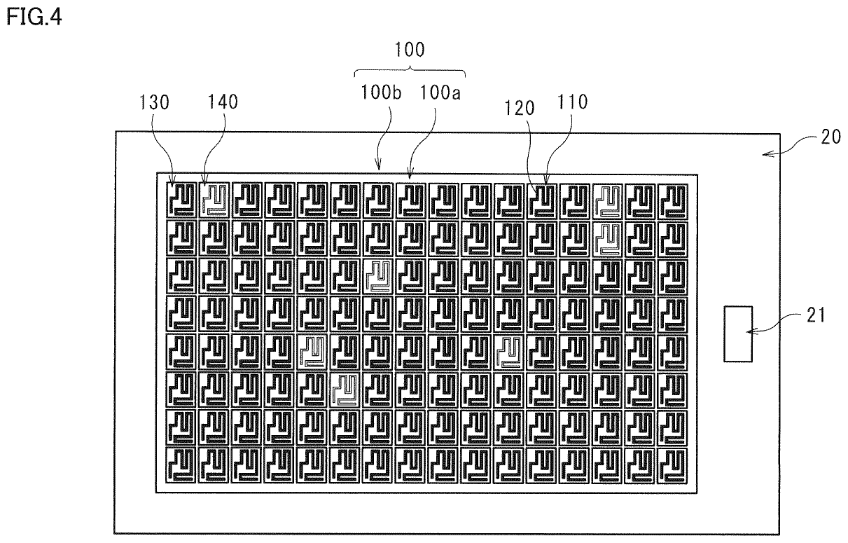

As shown in FIG. 4, in the determining step S1, an identification mark may be attached to a defective product 140. Such a configuration makes it possible to more reliably suppress mixing of defective products 140 into non-defective products 130.

When the identification mark is attached to defective product 140 in the determining step S1, the identification mark may be attached by the first laser beam in the determining step S1. In FIG. 4, conductive pattern 120 of defective product 140 is irradiated with the first laser beam to burn a part or the entirety of conductive pattern 120 to thereby form the identification mark. In other words, in the determining step S1, the identification mark is attached to printed wiring board piece 110 itself determined as defective product 140. Such a configuration makes it possible to easily distinguish non-defective products 130 and defective products 140 from each other in terms of appearance by the electrical inspection.

### Passing Step

As described above, in the passing step S2, the data about non-defective product 130 or defective product 140 obtained in the determining step S1 is passed on to the cutting-out step S3. The passing step S2 can be performed by a data controller 30 shown in FIG. 2.

Data controller 30 is provided to be capable of passing on, to the cutting-out step S3, the data about each printed wiring board piece 110 that has been determined as non-defective product 130 or defective product 140 by the electrical inspection conducted by electrical inspection device 10. Data controller 30 includes: a reception unit that receives data about the result of the electrical inspection conducted by electrical inspection device 10; and a transmission unit that transmits the data received by the reception unit to the cutting-out step S3. Data controller 30 may be configured to cause the transmission unit to directly transmit the data received by the reception unit, or may be configured to process the data received by the reception unit as necessary and thereafter cause the transmission unit to transmit the processed data.

The data passed on in the passing step S2 may be: only the data about printed wiring board piece 110 determined as non-defective product 130 in the electrical inspection; only the data about printed wiring board piece 110 determined as defective product 140 in the electrical inspection; or both the data about printed wiring board piece 110 determined as non-defective product 130 in the electrical inspection and the data about printed wiring board piece 110 determined as defective product 140 in the electrical inspection.

When a plurality of electrical inspections are performed on each printed wiring board piece 110 in the determining step S1, printed wiring board pieces 110 determined as failed in any one or more electrical inspections among all the electrical inspections are dealt as defective products 140 in the passing step S2. With such a configuration, the printed wiring board can be manufactured more efficiently.

The data passed on in the passing step S2, for example, may be different from or can be the same as the above-mentioned non-defectiveness/defectiveness determination data stored in non-contact tag 21. In the passing step S2, for example, the determination result in each electrical inspection may be passed on to the cutting-out step S3, or the final determination result in the determining step S1 may be passed on to the cutting-out step S3. In the passing step S2, the above-mentioned data can be passed on to the cutting-out step S3 without passing through non-contact tag 21 (i.e., independently of non-contact tag 21). On the other hand, when the data passed on in the passing step S2 is the same as the above-mentioned non-defectiveness/defectiveness determination data, the non-defectiveness/defectiveness determination data stored in non-contact tag 21 can be used also in the passing step S2.

### Cutting-Out Step

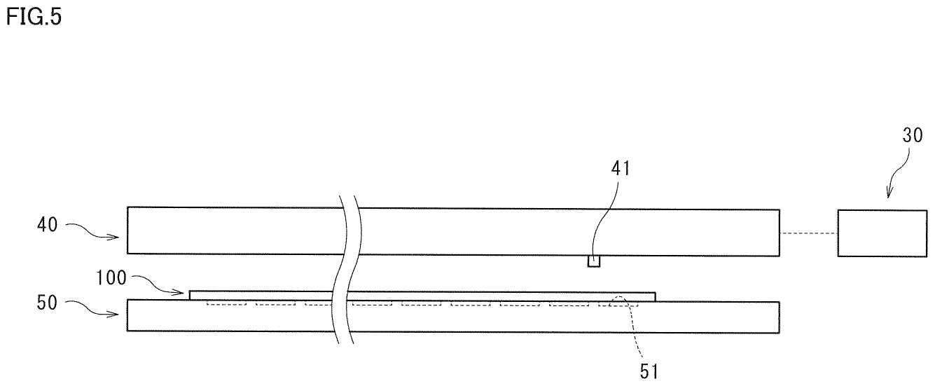

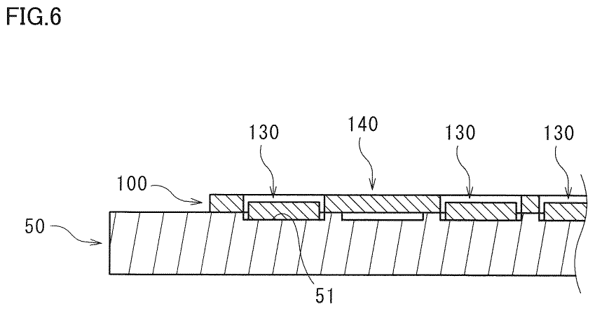

As shown in FIGS. 5 and 6, in the cutting-out step S3, while all printed wiring board pieces 110 determined as defective products 140 in the determining step S1 are left in printed wiring board sheet 100, all printed wiring board pieces 110 determined as non-defective products 130 in the determining step S1 are cut out from printed wiring board sheet 100. In the cutting-out step S3, non-defective product 130 is cut out along its outer edge. In the method of manufacturing a printed wiring board, a part of the outer edge of each of all printed wiring board pieces 110 may be cut out in advance, for example, before the determining step S1. In other words, each printed wiring board piece 110 may be provided to be connected by a seam to the above-mentioned connection portion. In this case, in the cutting-out step S3, the seam provided along the outer edge of non-defective product 130 should only be cut.

In the cutting-out step S3, non-defective product 130 is cut out by a cutting device 40. Cutting device 40 includes: a cutting portion that cuts out non-defective product 130; and a reception unit that receives data about non-defective product 130 or defective product 140, the data having been transmitted from data controller 30. Based on the data about non-defective product 130 or defective product 140 received from data controller 30, cutting device 40 selectively cuts out all printed wiring board pieces 110 from printed wiring board sheet 100 that have been determined as non-defective products 130 by electrical inspection device 10.

A specific configuration of the cutting portion is not particularly limited and may be a configuration, for example, including: a die that supports printed wiring board sheet 100; and a punch that punches out non-defective product 130 from printed wiring board sheet 100 supported by the die. Further, a specific configuration adaptable as the cutting portion may be a configuration in which non-defective product 130 is cut out by a laser beam as shown in FIG. 5. In this case, the cutting portion includes, for example, a laser head 41 capable of emitting a laser beam and a scanning unit (not shown) capable of scanning the laser beam emitted from laser head 41. Using the laser beam makes it easy to selectively cut out only non-defective product 130. Note that cutting device 40 may include a camera capable of recognizing the arrangement of printed wiring board pieces 110. Such a configuration makes it easier to selectively cut out only non-defective product 130.

When non-defective product 130 is cut out by the laser beam in the cutting-out step S3, non-defective product 130 may be cut out by the second laser beam higher in intensity than the first laser beam in the cutting-out step S3. Such a configuration makes it possible to easily and reliably attach the identification mark and cut out non-defective product 130. In other words, by attaching the identification mark with use of the first laser beam, the identification mark can be easily and reliably attached at low cost while suppressing damage to printed wiring board sheet 100 and first jig 20. Further, by using the second laser beam for cutting out non-defective product 130, non-defective product 130 can be easily and reliably cut out along its outer edge. The “intensity” of the laser beam means a value obtained by dividing the pulse energy (J) by the product of a pulse width (S) and an irradiation area (cm²).

Examples of the second laser beam used in the cutting-out step S3 include a YAG laser beam and a fiber laser beam. Examples of the YAG laser beam include a UV-YAG laser beam.

The lower limit of the wavelength of the second laser beam may be, for example, 280 nm or 320 nm. On the other hand, the upper limit of the wavelength may be, for example, 500 nm or 400 nm. Further, the wavelength of the second laser beam may be fixed.

In the cutting-out step S3, printed wiring board sheet 100 is held by a second jig 50. In other words, in the cutting-out step S3, printed wiring board sheet 100 is held by second jig 50 different from first jig 20 used in the determining step S1. Such a configuration makes it possible to easily and reliably perform both the electrical inspection in the determining step S1 and the cutting out of non-defective product 130 in the cutting-out step S3. Second jig 50 may have a positioning portion for determining the position of printed wiring board sheet 100 with respect to second jig 50 and the position of second jig 50 with respect to cutting device 40. Further, second jig 50 may not be provided with non-contact tag 21 mentioned above.

Second jig 50 has a receiving portion 51 that receives non-defective product 130 that has been cut out from printed wiring board sheet 100. With such a configuration, non-defective product 130 can be easily and reliably separated from printed wiring board sheet 100 from which each defective product 140 has not been cut out, as shown in FIG. 6.

Second jig 50 is a plate member having recesses corresponding to the plurality of printed wiring board pieces 110. Examples of the main component of second jig 50 include metals such as aluminum. The recess is configured as receiving portion 51. In the cutting-out step S3, when non-defective product 130 is cut out, printed wiring board sheet 100 may be suctioned toward second jig 50.

The recess is formed to be recessed from a surface of a plate (a surface of a portion where no recess is formed) of second jig 50. The recess is formed to have a depth, for example, such that the surface of non-defective product 130 cut out from printed wiring board sheet 100 protrudes from the surface of the plate. With such a configuration, non-defective product 130 supported by receiving portion 51 may be able to be easily moved to the next step. For example, in the state in which printed wiring board sheet 100 is held by second jig 50 and the plurality of non-defective products 130 are supported by receiving portion 51, these non-defective products 130 can be easily suctioned from the direction normal to the surface of the plate. As a result, only the plurality of non-defective products 130 cut out in the cutting-out step S3 can be easily and reliably moved to the next step. From this point of view, the method of manufacturing a printed wiring board may include a step of suctioning non-defective product 130 cut out in the cutting-out step S3. The suctioning step can be performed, for example, with use of a robot hand capable of approaching the plurality of non-defective products 130 from the above-mentioned direction normal to the surface of the plate.

### Appearance Inspecting Step

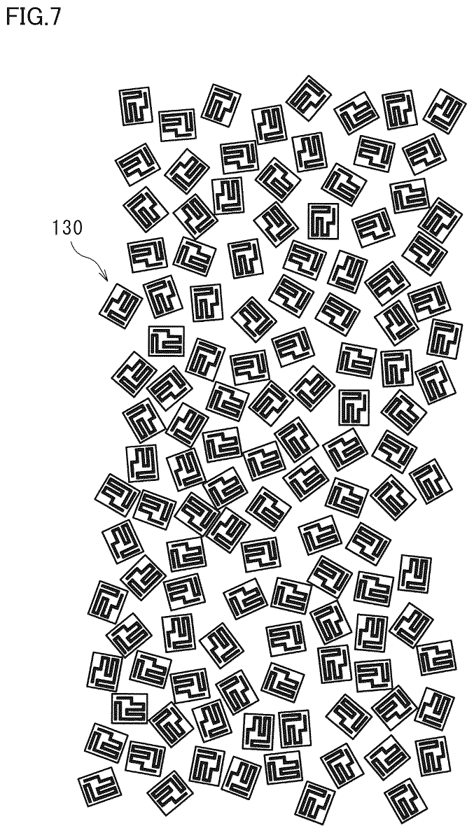

As shown in FIG. 7, in the appearance inspecting step S4, the appearance inspection is performed on the plurality of non-defective products 130 that have been cut out in the cutting-out step S3 and separated from printed wiring board sheet 100. In other words, in the appearance inspecting step S4, the appearance inspection is performed only on the plurality of non-defective products 130 separated from printed wiring board sheet 100.

### System of Manufacturing Printed Wiring Board

A system of manufacturing a printed wiring board according to one aspect of the present disclosure is a system of manufacturing a printed wiring board from a printed wiring board sheet having a plurality of printed wiring board pieces. The system of manufacturing a printed wiring board can perform the above-described method of manufacturing a printed wiring board. The system of manufacturing a printed wiring board is configured to be capable of manufacturing a printed wiring board from printed wiring board sheet 100 described above.

The system of manufacturing a printed wiring board includes: a determination device that determines, by an electrical inspection, whether each of the plurality of printed wiring board pieces is a non-defective product or a defective product; a cutting device that selectively cuts out the non-defective product from the printed wiring board sheet; and an appearance inspection device that inspects an appearance of the non-defective product cut out by the cutting device. The system of manufacturing a printed wiring board further includes a data controller that passes on data about a non-defective product or a defective product to the cutting device, the data about a non-defective product or a defective product being obtained in the determination device. The system of manufacturing a printed wiring board causes the cutting device to cut out the non-defective product based on the data passed on from the data controller.

According to the system of manufacturing a printed wiring board, the cutting device can selectively cut out the non-defective product from the printed wiring board sheet based on the data passed on from the data controller. In the system of manufacturing a printed wiring board, the defective product is not cut out from the printed wiring board sheet, which makes it possible to suppress mixing of the defective products into the non-defective products. Further, such a configuration makes it possible to reduce the loss resulting from processing of the defective products. Further, according to the system of manufacturing a printed wiring board, the appearance inspection device can inspect only the non-defective products cut out by the cutting device, so that the efficiency in manufacturing of the printed wiring board can be enhanced.

### Determination Device

The determination device is configured to be capable of performing the above-described determining step S1. The determination device is configured to include electrical inspection device 10 described above. The determination device is configured to perform an electrical inspection in the state in which printed wiring board sheet 100 is held by first jig 20. First jig 20 is provided with non-contact tag 21. The determination device may be configured to attach an identification mark to defective product 140. In this case, the determination device may be configured to attach the identification mark by the first laser beam.

### Data Controller

The data controller is configured to be capable of performing the passing step S2 described above. As the data controller, data controller 30 in FIG. 2 can be used.

### Cutting Device

The cutting device is configured to be capable of performing the cutting-out step S3 described above. As the cutting device, cutting device 40 in FIG. 5 can be used. The cutting device is configured to cut out non-defective product 130 in the state in which printed wiring board sheet 100 is held by second jig 50.

### Appearance Inspection Device

The appearance inspection device is configured to be capable of performing the appearance inspecting step S4 described above. A specific configuration of the appearance inspection device is not particularly limited and a known configuration can be adopted.

### Second Embodiment

### Method of Manufacturing Printed Wiring Board

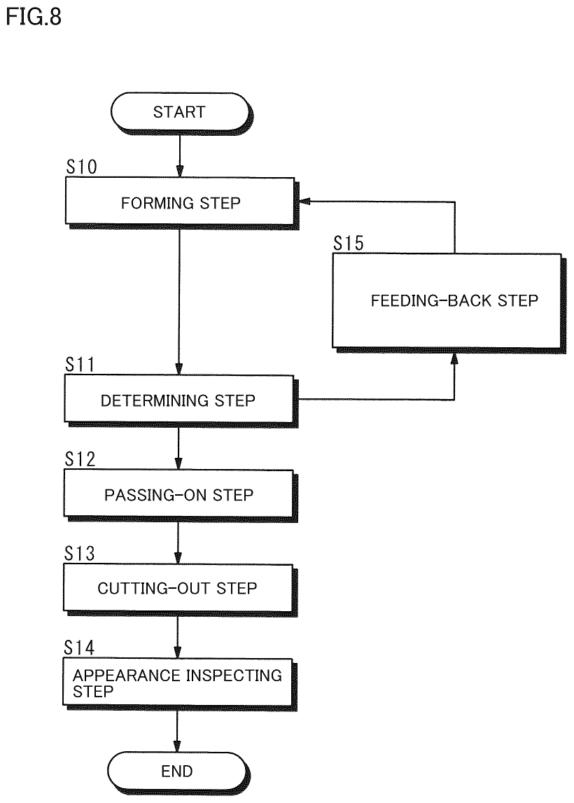

A method of manufacturing a printed wiring board shown in FIG. 8 is a method of manufacturing a printed wiring board from a printed wiring board sheet having a plurality of printed wiring board pieces. In the method of manufacturing a printed wiring board, a plurality of printed wiring boards are manufactured from one large-sized printed wiring board sheet.

The method of manufacturing a printed wiring board includes: a forming step S10 of forming a conductive pattern on each of a plurality of printed wiring board pieces; a determining step S11 of determining, by an electrical inspection conducted on the conductive pattern, whether each of the plurality of printed wiring board pieces is a non-defective product or a defective product; a cutting-out step S13 of, after the determining step S11, selectively cutting out the non-defective product from the printed wiring board sheet; and an appearance inspecting step S14 of inspecting an appearance of the non-defective product cut out in the cutting-out step S13. Further, the method of manufacturing a printed wiring board includes: a passing step S12 of passing on data about a non-defective product or a defective product to the cutting-out step S13, the data about a non-defective product or a defective product being obtained in the determining step S11; and a feeding-back step S15 of feeding back the data about a defective product obtained in the determining step S11 to a step prior to the determining step S11, in order to reduce the number of defective products. In the method of manufacturing a printed wiring board, the non-defective product is cut out in the cutting-out step S13 based on the data passed on in the passing step S12.

The method of manufacturing a printed wiring board can suppress mixing of the defective products into the non-defective products, similarly to the method of manufacturing a printed wiring board in the first embodiment. Further, the method of manufacturing a printed wiring board includes the feeding-back step S15, which makes it easy to suppress the occurrence of the defective product. As a result, the efficiency in manufacturing of the printed wiring board can be further enhanced.

The determining step S11, the passing step S12, the cutting-out step S13, and the appearance inspecting step S14 in the method of manufacturing a printed wiring board can be performed in the same procedure as that in the method of manufacturing a printed wiring board in the first embodiment. Thus, the following describes only the forming step S10 and the feeding-back step S15.

### Forming Step

In the forming step S10, the conductive pattern is formed, for example, by a semi-additive method or a subtractive method. In the semi-additive method, for example, a conductive underlying layer is formed on a substrate, a resist pattern is formed on the conductive underlying layer, a plating layer is formed at an opening of the resist pattern, the resist pattern is removed, and thereafter, a non-stacked region of the plating layer in the conductive underlying layer is etched with use of the plating layer as a mask to thereby form a conductive pattern. In the subtractive method, for example, a conductive underlying layer is formed on a substrate, a plating layer is formed on the conductive underlying layer, a resist pattern is formed on the plating layer, the plating layer and the conductive underlying layer are etched with use of this resist pattern as a mask, and thereafter, the resist pattern is removed to thereby form a conductive pattern.

### Feeding-Back Step

In the feeding-back step S15, the data about the defective product obtained in the determining step S11 is fed back to the forming step S10. In the feeding-back step S15, for example, the data about the arrangement of defective products on the printed wiring board sheet is fed back to the forming step S10. More specifically, in the feeding-back step S15, the data about the arrangement of the defective products on the printed wiring board sheet is accumulated in a server or the like, and fed back to the forming step S10 such that the occurrence of defective products can be suppressed while manufacturing other printed wiring boards. In the method of manufacturing a printed wiring board, the defective product may occur more frequently at the same position on the printed wiring board sheet, which may be caused by a photofabrication method or a plating method in the forming step S10. In this case, if the same photofabrication method or the same plating method is continuously used, there is a high possibility that the defective product may continuously occur at the same position on the printed wiring board sheet. On the other hand, in the feeding-back step S15, the data about the arrangement of the defective products on the printed wiring board sheet is fed back to the forming step S10, so that defects resulting from the photofabrication method and the plating method can be found at early timing. As a result, the occurrence of the defective products can be suppressed.

When a plurality of electrical inspections are performed on each printed wiring board piece in the determining step S11, in the feeding-back step S15, the result of each electrical inspection may be fed back to the forming step S10. Such a configuration makes it easy to specify the cause of the defect in the forming step S10.

### System of Manufacturing Printed Wiring Board

The system of manufacturing a printed wiring board in the present embodiment is a system of manufacturing a printed wiring board from a printed wiring board sheet having a plurality of printed wiring board pieces. The system of manufacturing a printed wiring board includes: a conductive pattern forming device that forms a conductive pattern on each of a plurality of printed wiring board pieces; a determination device that determines, by an electrical inspection conducted on the conductive pattern, whether each of the plurality of printed wiring board pieces is a non-defective product or a defective product; a cutting device that selectively cuts out the non-defective product from the printed wiring board sheet; and an appearance inspection device that inspects an appearance of the non-defective product cut out by the cutting device. Further, the system of manufacturing a printed wiring board includes: a data controller that passes on data about a non-defective product or a defective product obtained in the determination device to the cutting device; and a feedback device that feeds back the data about a defective product obtained in the determination device to the conductive pattern forming device in order to reduce the number of defective products. The system of manufacturing a printed wiring board causes the cutting device to cut out the non-defective product based on the data passed on from the data controller.

The system of manufacturing a printed wiring board can be configured similarly to the system of manufacturing a printed wiring board in the first embodiment except that it includes the conductive pattern forming device and the feedback device described above.

The system of manufacturing a printed wiring board can suppress mixing of the defective products into the non-defective products, similarly to the system of manufacturing a printed wiring board in the first embodiment. Further, the system of manufacturing a printed wiring board includes the above-mentioned feedback device capable of feeding back the data about a defective product obtained in the determination device to the conductive pattern forming device, so that the occurrence of the defective product is easily suppressed. As a result, the efficiency in manufacturing of the printed wiring board can be further enhanced.

### Other Embodiments

It should be understood that the embodiments disclosed herein are illustrative and non-restrictive in every respect. The scope of the present invention is not limited to the configurations of the embodiments as described above, but is defined by the terms of the claims, and is intended to include all modifications within the meaning and scope equivalent to the terms of the claims.

Specific configurations, arrangements, and the like of the plurality of printed wiring board pieces in the printed wiring board sheet described above are not limited to the configurations described in the above embodiments. For example, the printed wiring board pieces each may be configured such that the substrates are arranged in multiple layers. Further, the procedure of forming the conductive pattern, the procedure of the electrical inspection, the procedure of cutting out the printed wiring board pieces, the procedure of the appearance inspection, and the like can be set according to the quality and the like required for the printed wiring board.

In each of the configurations described in the above embodiments, the identification mark is attached to each printed wiring board piece in the determining step. However, in the determining step, the identification mark can also be attached to a portion on the printed wiring board sheet other than each printed wiring board piece. The identification mark may also be attached by a method other than laser beams. Further, in the determining step, it is possible that the identification mark may not be attached.

In each of the configurations described in the above embodiments, the first jig is used in the determining step, and the second jig is used in the cutting-out step. However, there is no limitation on a specific configuration of the jig used in the determining step and the cutting-out step. For example, the jig used in the determining step does not have to be provided with the above-described non-contact tag. Further, in the determining step and the cutting-out step, the printed wiring board sheet may be held by the same jig. In this case, a jig having the above-mentioned receiving portion for receiving a non-defective product cut out from the printed wiring board sheet may be used.

### REFERENCE SIGNS LIST

10 electrical inspection device
20 first jig
21 non-contact tag
30 data controller
40 cutting device
41 laser head
50 second jig
51 receiving portion
100 printed wiring board sheet
100a array portion
100b peripheral portion
110 printed wiring board piece
120 conductive pattern
130 non-defective product
140 defective product

1. A method of manufacturing a printed wiring board from a printed wiring board sheet having a plurality of printed wiring board pieces, the method comprising:
determining, by an electrical inspection, whether each of the plurality of printed wiring board pieces is a non-defective product or a defective product;
after the determining, selectively cutting out the non-defective product from the printed wiring board sheet; and
inspecting an appearance of the non-defective product cut out in the cutting out,
the method further comprising passing on data about a non-defective product or a defective product to the cutting out, the data about a non-defective product or a defective product being obtained in the determining, wherein
in the cutting out, the non-defective product is cut out based on the data passed on in the passing on.

2. The method of manufacturing a printed wiring board according to claim 1, wherein, in the determining, an identification mark is attached to the defective product.

3. The method of manufacturing a printed wiring board according to claim 2, wherein
in the determining, the identification mark is attached by a first laser beam, and
in the cutting out, the non-defective product is cut out by a second laser beam higher in intensity than the first laser beam.

4. The method of manufacturing a printed wiring board according to claim 1, wherein
in the determining, the printed wiring board sheet is held by a first jig, and
the first jig is provided with a non-contact tag capable of storing non-defectiveness/defectiveness determination data obtained in the determining.

5. The method of manufacturing a printed wiring board according to claim 1, wherein
in the cutting out, the printed wiring board sheet is held by a second jig, and
the second jig has a receiving portion that receives the non-defective product cut out from the printed wiring board sheet.

6. The method of manufacturing a printed wiring board according to claim 1, further comprising feeding back data about a defective product to a step prior to the determining in order to reduce defective products in number, the data about a defective product being obtained in the determining.

7. A system of manufacturing a printed wiring board from a printed wiring board sheet having a plurality of printed wiring board pieces, the system comprising:
a determination device that determines, by an electrical inspection, whether each of the plurality of printed wiring board pieces is a non-defective product or a defective product;
a cutting device that selectively cuts out the non-defective product from the printed wiring board sheet; and
an appearance inspection device that inspects an appearance of the non-defective product cut out by the cutting device,
the system further comprising a data controller that passes on data about a non-defective product or a defective product to the cutting device, the data about a non-defective product or a defective product being obtained in the determination device, wherein
the cutting device cuts out the non-defective product based on the data passed on from the data controller.
